(19) United States
(12) Patent Application Publication
(10) Pub. No.: US 2018/0331091 A1
(43) Pub. Date: Nov. 15, 2018

(54) DETECTION DEVICE AND METHOD FOR GATE DRIVE CIRCUIT

(71) Applicant: Wuhan China Star Optoelectronics Technology Co., Ltd., Wuhan, Hubei (CN)

(72) Inventor: Jinglong Wang, Wuhan, Hubei (CN)

(73) Assignee: Wuhan China Star Optoelectronics Technology Co., Ltd., Wuhan, Hubei (CN)

(21) Appl. No.: 15/523,047

(22) PCT Filed: Mar. 14, 2017
(86) PCT No.: PCT/CN2017/076553

§ 371 Date: Aug. 2, 2018

(30) Foreign Application Priority Data
Feb. 23, 2017 (CN) 201710099275.9

(51) Int. Cl. H01L 27/02; H01L 21/66; G09G 3/00

(52) U.S. Cl. CPC H01L 27/0251; G09G 3/006; H01L 22/32

(57) ABSTRACT

A detection device for a gate drive circuit and a detection method for the gate drive circuit are disclosed. In a connecting element of the detection device, a first end of the first connecting part is electrically connected with an output end of the gate drive circuit, and a second end thereof is electrically connected with the third connecting part. A first end of the second connecting part is electrically connected with the test pad, and a second end thereof is electrically insulated from the third connecting part. According to the present disclosure, the gate drive circuit can be prevented from being destroyed by electrostatic discharge (ESD), and a qualified rate of a liquid crystal display panel can be improved.

### CROSS REFERENCE TO RELATED APPLICATION

The present application claims priority of Chinese patent application CN201710099275.9, entitled “Detection Device and Method for Gate Drive Circuit” and filed on Feb. 23, 2017, the entirety of which is incorporated herein by reference.

### FIELD OF THE INVENTION

The present disclosure relates to the technical field of display, and particularly to a detection device for a gate drive circuit and a detection method for the gate drive circuit.

### BACKGROUND OF THE INVENTION

At present, more and more liquid crystal display panels adopt a Gate Driver on Array (GOA) technology to reduce a frame width of an array substrate thereof and to meet the narrow frame development trend of the liquid crystal display panel. In order to detect and analyze a signal output by an abnormal liquid crystal display panel, a corresponding detect circuit should be added.

In a detect circuit for detecting a gate drive circuit of a Thin Film Transistor Liquid Crystal Display (TFT-LCD) in the prior art, an output end of the gate drive circuit is directly connected with a test pad through a metal wiring. When an abnormity of a panel is detected, a signal output by the test pad is detected by a probe of the TFT-LCD, whereby whether the gate drive circuit of the TFT-LCD is in an abnormal state can be determined. However, the test pad is generally made of a large block of metal, and in the large block of metal, an electrostatic charge risk can be easily resulted in. During a production and transportation procedure of a product, since the test pad is always connected with the output end of the gate drive circuit, an electrostatic discharge (ESD) would be easily resulted in and conducted to the gate drive circuit. As a result, the TFT of the gate drive circuit would be broken down and destroyed.

### SUMMARY OF THE INVENTION

In the prior art, an output end of a gate drive circuit is always connected with a test pad which is made of a large block of metal. During a production and transportation procedure of a product, since the output end of the gate drive circuit is always connected with the test pad, an electrostatic discharge (ESD) would be easily resulted in and conducted to the gate drive circuit. As a result, the TFT of the gate drive circuit would be broken down and destroyed. The present disclosure aims to solve the aforesaid technical problem.

In order to solve the aforesaid technical problem, the present disclosure provides a detection device and a detection method for the gate drive circuit.

According to a first aspect, the present disclosure provides a detection device for a gate drive circuit, which comprises a test pad and a connecting element for electrically connecting the gate drive circuit and the test pad, wherein the connecting element comprises a first connecting part, a second connecting part, and a third connecting part;

wherein a first end of the first connecting part is electrically connected with an output end of the gate drive circuit, and a first end of the second connecting part is electrically connected with the test pad; and

wherein a second end of the first connecting part is electrically connected with the third connecting part, and a second end of the second connecting part is electrically insulated from the third connecting part.

Preferably, the first connecting part and the second connecting part are arranged on a first metal layer. The third connecting part is arranged on a second metal layer. The first metal layer and the second metal layer are insulated from each other.

Preferably, an insulation layer is arranged between the first metal layer and the second metal layer, so that the first metal layer and the second metal layer are insulated from each other.

Preferably, the insulation layer is provided with at least one via hole, and the second end of the first connecting part is electrically connected with the third connecting part through the via hole.

Preferably, the first metal layer further comprises a pattern of a scanning line of a display panel and a pattern of a gate of a switching element of the display panel.

Preferably, the second metal layer further comprises a pattern of a data line of a display panel and a pattern of a source and a drain of a switching element of the display panel.

Preferably, the insulation layer is made of silicon nitride. The first metal layer is made of Mo/Al, and the second metal layer is made of Mo/Al/Ge.

Preferably, when an abnormity of a panel is detected, an insulating material between the second end of the second connecting part and the third connecting part is melted by a laser so that the second end of the second connecting part and the third connecting part are electrically connected with each other.

According to a second aspect, the present disclosure provides a detection method for a gate drive circuit, which comprises following steps:

providing a detection device, which comprises a test pad and a connecting element for electrically connecting the gate drive circuit and the test pad,
wherein the connecting element comprises a first connecting part, a second connecting part, and a third connecting part;
wherein a first end of the first connecting part is electrically connected with an output end of the gate drive circuit, and a first end of the second connecting part is electrically connected with the test pad; and
wherein a second end of the first connecting part is electrically connected with the third connecting part, and a second end of the second connecting part is electrically insulated from the third connecting part;

determining whether the gate drive circuit needs to be detected; and

if yes, melting an insulating material between the second end of the second connecting part and the third connecting part by a laser, so that the second end of the second connecting part and the third connecting part are electrically connected with each other and an output signal of the gate drive circuit is output through the connecting element and the test pad in sequence.

Preferably, the method further comprises a step of determining a state of the gate drive circuit according to a signal output by the test pad.

Compared with the prior art, one embodiment or a plurality of embodiments according to the present disclosure may have the following advantages or beneficial effects.

In the detection device for the gate drive circuit according to the present disclosure, the third connecting part is equivalent to a onetime switch through which the first connecting part and the second connecting part are electrically connected with each other when an abnormity of a panel is detected. It can be seen that, when the panel does not need to be detected, the first connecting part and the second connecting part are disconnected with each other. When the panel is detected, the first connecting part and the second connecting part are electrically connected with each other through the third connecting part, so that an output signal of the gate drive circuit can be conducted to the test pad through the first connecting part, the third connecting part, and the second connecting part in sequence. Therefore, the gate drive circuit will not be destroyed by ESD as the detection device in the prior art in which the output end of the gate drive circuit is always connected with the test pad, and the TFT of the gate drive circuit can be prevented from being broken down and destroyed. In other words, according to the present disclosure, a qualified rate of the liquid crystal display panel can be improved.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The accompanying drawings provide further understandings of the present disclosure and constitute one part of the description. The drawings are used for interpreting the present disclosure together with the embodiments, not for limiting the present disclosure. In the drawings:

FIG. 1 schematically shows a structure of a detection device for a gate drive circuit according to one embodiment of the present disclosure;

FIG. 2 is a sectional view of an overlapping region of the second connecting part and the third connecting part when a panel does not need to be detected;

FIG. 3 is a sectional view of the overlapping region of the second connecting part and the third connecting part when the panel is detected; and

FIG. 4 is a flow chart of a detection method for the gate drive circuit according to one embodiment of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It should be noted that, as long as there is no conflict, all the technical features mentioned in all the embodiments may be combined together in any manner, and the technical solutions obtained in this manner all fall within the scope of the present disclosure.

The technical problem to be solved by the present disclosure is stated as follows. In the prior art, an output end of a gate drive circuit is always connected with a test pad which is made of a large block of metal. During a production and transportation procedure of a product, since the output end 4 of the gate drive circuit is always connected with the test pad 5, an electrostatic discharge (ESD) would be easily resulted in and conducted to the gate drive circuit. As a result, the TFT of the gate drive circuit would be broken down and destroyed. In order to solve the aforesaid technical problem, the embodiment of the present disclosure provides a detection device for the gate drive circuit.

### Embodiment 1

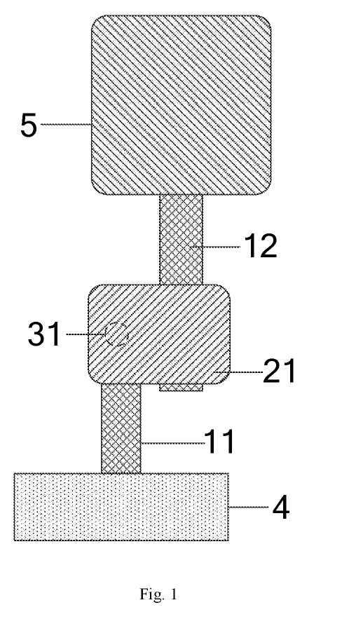

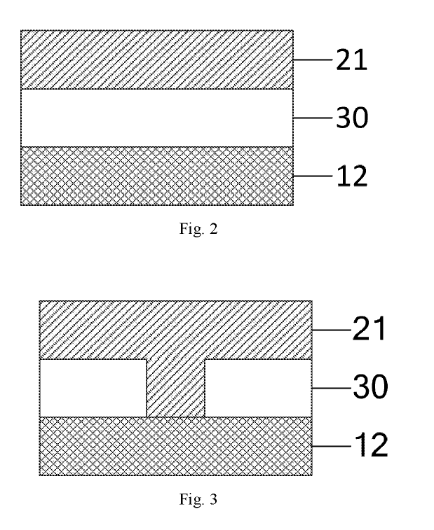

FIG. 1 schematically shows a structure of a detection device for a gate drive circuit according to the present embodiment. As shown in FIG. 1, according to the present embodiment, the detection device for the gate drive circuit mainly comprises a first connecting part 11, a second connecting part 12, and a third connecting part 21. The first connecting part 11, the second connecting part 12, and the third connecting part 21 are all metal connecting parts. The first connecting part 11 and the second connecting part 12 are arranged on a first metal layer. That is, the first metal layer comprises a pattern of the first connecting part 11 and a pattern of the second connecting part 12. The first connecting part 11 and the second connecting part 12 are arranged spaced from each other. The third connecting part 21 is arranged on a second metal layer. Here, the second metal layer is different from the first metal layer. The second metal layer comprises a pattern of the third connecting part 21. As shown in FIG. 2, an insulation layer 30 is arranged between the first metal layer and the second metal layer.

A first end of the first connecting part 11 is electrically connected with an output end 4 of the gate drive circuit. That is, the first end of the first connecting part 11 is electrically connected with a tested object, i.e., the gate drive circuit. A first end of the second connecting part 12 is electrically connected with the test pad 5.

A second end of the first connecting part 11 is electrically connected with the third connecting part 21 through a via hole 31 arranged in the insulation layer 30. In this manner, the second end of the first connecting part 11 is always electrically connected with the third connecting part 21.

According to one preferred embodiment of the present disclosure, the second end of the first connecting part 11 is electrically connected with the third connecting part 21 through at least two via holes 31 arranged in the insulation layer 30. Here, a quantity of the via hole 31 is an integer larger than or equal to 2. It can be seen that, according to the present embodiment, the first connecting part 11 can be stably connected with the third connecting part 21, and thus a signal can be transmitted in a more stable and reliable manner.

More importantly, a second end of the second connecting part 12 is electrically insulated from the third connecting part 21. According to the present embodiment, the third connecting part 21 is separated from the second connecting part 12 by the insulation layer 30.

In the detection device for the gate drive circuit according to the present embodiment, when a liquid crystal display panel is in a normal state (i.e., the panel does not need to be detected), the second end of the second connecting part 12 is electrically insulated from the third connecting part 21, and thus the output end 4 of the gate drive circuit is electrically insulated from the test pad 5. In this manner, the gate drive circuit will not be destroyed by ESD as the detection device in the prior art in which the output end of the gate drive circuit is always connected with the test pad, and a TFT of the gate drive circuit can be prevented from being broken down and destroyed. In other words, according to the present embodiment, a qualified rate of the liquid crystal display panel can be improved.

### Embodiment 2

According to the present embodiment, the structure of the detection device according to embodiment 1 is further optimized.

According to the present embodiment, when there is an abnormity in the liquid crystal panel and the gate drive circuit of the panel needs to be detected, an insulating material (i.e., the insulating material of the insulation layer 30) between the second end of the second connecting part 12 and the third connecting part 21 is melted by a laser, so that the second end of the second connecting part 12 and the third connecting part 21 are electrically connected with each other.

FIG. 2 is a sectional view of an overlapping region of the second connecting part 12 and the third connecting part 21 when the panel does not need to be detected. As shown in FIG. 2, when the panel does not need to be detected, the second end of the second connecting part 12 is electrically insulated from the third connecting part 21 by the insulation layer 30. FIG. 3 is a sectional view of the overlapping region of the second connecting part 12 and the third connecting part 21 when the panel is detected. As shown in FIG. 3, when the panel is detected, the insulating material between the third connecting part 21 and the second end of the second connecting part 12 is melted by the laser.

Specifically, the laser has properties of high brightness, high directionality, high monochrome, and high coherence. A high temperature up to thousands of centigrade degrees or even tens of thousands of centigrade degrees can be generated above the third connecting part 21 by the laser. A region on a surface of the third connecting part 21 that is irradiated by the laser can be melted, and thus a flowing liquid metal can be formed. The liquid metal passes through the insulation layer 30 and contacts the second connecting part 12. In this manner, the second end of the second connecting part 12 and the third connecting part 21 can be electrically connected with each other. That is, the second end of the second connecting part 12 and the third connecting part 21 can be electrically connected with each other by the laser.

It can be seen that, when the panel does not need to be detected, the second end of the second connecting part 12 and the third connecting part 21 are electrically insulated from each other. The second end of the second connecting part 12 and the third connecting part 21 are electrically connected with each other only when the panel is detected.

When the second end of the second connecting part 12 and the third connecting part 21 are electrically connected with each other, a signal transmission channel can be formed, i.e., the output end 4 of the gate drive circuit, the first connecting part 11, the third connecting part 21, the second connecting part 12, and the test pad 5. That is, an output signal of the gate drive circuit is transmitted to the test pad 5 through the first connecting part 11, the third connecting part 21, and the second connecting part 12 in sequence. The signal transmission channel can only be formed when the panel is detected. In this manner, the gate drive circuit will not be destroyed by ESD as the detection device in the prior art in which the output end of the gate drive circuit is always connected with the test pad, and the TFT of the gate drive circuit can be prevented from being broken down and destroyed.

According to the present embodiment, the second end of the second connecting part 12 and the third connecting part 21 can be electrically connected with each other by the laser when the panel is detected.

In the detection device according to the present embodiment, the third connecting part 21 is equivalent to a onetime switch through which the first connecting part 11 and the second connecting part 12 are electrically connected with each other when an abnormity of a panel is detected. It can be seen that, when the panel does not need to be detected, the first connecting part 11 and the second connecting part 12 are disconnected with each other. When the panel is detected, the first connecting part 11 and the second connecting part 12 are electrically connected with each other through the third connecting part 21, so that an output signal of the gate drive circuit can be conducted to the test pad 5 through the first connecting part 11, the third connecting part 21, and the second connecting part 12 in sequence.

Therefore, the gate drive circuit will not be destroyed by ESD as the detection device in the prior art in which the output end of the gate drive circuit is always connected with the test pad, and the TFT of the gate drive circuit can be prevented from being broken down and destroyed. In other words, according to the present disclosure, a qualified rate of the liquid crystal display panel can be improved.

Moreover, according to the present embodiment, a structure of each connecting part is simple, and thus an output signal can be effectively transmitted to the test pad 5 when the panel is detected.

### Embodiment 3

According to the present embodiment, a pattern of the first metal layer, a pattern of the second metal layer, a material of each metal layer, and the material of the insulation layer 30 are optimized based on embodiment 1 or embodiment 2.

According to the present embodiment, in addition to the pattern of the first connecting part 11 and the pattern of the second connecting part 12, the first metal layer further comprises a pattern of a scanning line of the display panel and a pattern of a gate of a switching element of the display panel. That is, the first connecting part 11 and the second connecting part 12 are arranged in a same layer as the scanning line of the display panel and the gate of the switching element thereof. It can be seen that, according to the present embodiment, a manufacturing procedure of the display panel can be reduced. Here, the first metal layer is preferably made of Mo/Al double layers metal structure, but the present disclosure is not limited by this. For example, the first metal layer can also be made of Mo/W double layers metal structure or Al single layer metal structure.

According to the present embodiment, in addition to the pattern of the third connecting part 21, the second metal layer further comprises a pattern of a data line of the display panel and a pattern of a source and a drain of the switching element of the display panel. That is, the third connecting part 21 is arranged in a same layer as the data line of the display panel and the source and the drain of the switching element thereof. It can be seen that, according to the present embodiment, the manufacturing procedure of the display panel can be reduced. Here, the second metal layer is preferably made of Mo/Al/Ge triple layers metal structure, but the present disclosure is not limited by this. For example, the second metal layer can also be made of Ti/Al/Ti triple layers metal structure.

According to the present embodiment, the insulation layer 30 is made of silicon nitride. The material of the insulation layer 30 can be one or two selected from SiNx and SiOx. It should be noted that, according to the embodiment of the present disclosure, the material of the insulation layer 30 is not defined, as long as a performance requirement of the detection device for the gate drive circuit can be met.

### Embodiment 4

The present embodiment provides a detection method based on the detection device for the gate drive circuit of embodiment 1, embodiment 2, or embodiment 3.

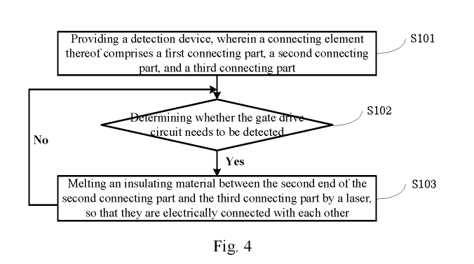

FIG. 4 is a flow chart of the detection method for the gate drive circuit according to the present embodiment. As shown in FIG. 4, according to the present embodiment, the detection method for the gate drive circuit mainly comprises step S101 to step S103.

As shown in FIGS. 1 to 3, in step S101, a detection device is provided. The detection device comprises a test pad 5 and a connecting element for electrically connecting the gate drive circuit and the test pad 5. The connecting element comprises a first connecting part 11, a second connecting part 12, and a third connecting part 21. The first metal layer comprises a pattern of the first connecting part 11 and a pattern of the second connecting part 12, and the second metal layer comprises a pattern of the third connecting part 21. In addition, an insulation layer 30 is arranged between the first metal layer and the second metal layer. A first end of the first connecting part 11 is electrically connected with an output end 4 of the gate drive circuit, and a first end of the second connecting part 12 is electrically connected with the test pad 5. A second end of the first connecting part 11 is electrically connected with the third connecting part 21, and a second end of the second connecting part 12 is electrically insulated from the third connecting part 21.

Specifically, the detection device provided by step S101 is the detection device according to embodiment 1, embodiment 2, or embodiment 3.

In step S102, whether the gate drive circuit needs to be detected is determined.

In step S103, if a determination result of step S102 is yes, an insulating material between the second end of the second connecting part 12 and the third connecting part 21 is melted by a laser, so that the second end of the second connecting part 12 and the third connecting part 21 are electrically connected with each other and an output signal of the gate drive circuit is output through the connecting element and the test pad 5 in sequence. If the determination result of step S102 is no, step S102 is returned. According to one preferred embodiment, the method further comprises a step of determining a state of the gate drive circuit according to a signal output by the test pad 5.

Specifically, the laser has properties of high brightness, high directionality, high monochrome, and high coherence. A high temperature up to thousands of centigrade degrees or even tens of thousands of centigrade degrees can be generated above the third connecting part 21 by the laser. A region on a surface of the third connecting part 21 that is irradiated by the laser can be melted, and thus a flowing liquid metal can be formed. The liquid metal passes through the insulation layer 30 and contacts the second connecting part 12. In this manner, the second end of the second connecting part 12 and the third connecting part 21 can be electrically connected with each other. That is, the second end of the second connecting part 12 and the third connecting part 21 can be electrically connected with each other by the laser.

Accordingly, a signal transmission channel can be formed, i.e., the output end 4 of the gate drive circuit, the first connecting part 11, the third connecting part 21, the second connecting part 12, and the test pad 5. That is, an output signal of the gate drive circuit is transmitted to the test pad 5 through the first connecting part 11, the third connecting part 21, and the second connecting part 12 in sequence. The second connecting part 12 and the third connecting part 21 can only be electrically connected with each other when the panel is detected. Therefore, the gate drive circuit will not be destroyed by ESD as the detection device in the prior art in which the output end of the gate drive circuit is always connected with the test pad, and the TFT of the gate drive circuit can be prevented from being broken down and destroyed.

According to the present embodiment, the second end of the second connecting part 12 and the third connecting part 21 can be electrically connected with each other by the laser when the panel is detected.

In a word, in the detection method for the gate drive circuit according to the present embodiment, the third connecting part 21 of the detection device is equivalent to a onetime switch through which the first connecting part 11 and the second connecting part 12 are electrically connected with each other when an abnormity of a panel is detected. It can be seen that, when the panel does not need to be detected, the first connecting part 11 and the second connecting part 12 are disconnected with each other. When the panel is detected, the first connecting part 11 and the second connecting part 12 are electrically connected with each other through the third connecting part 21, so that an output signal of the gate drive circuit can be conducted to the test pad 5 through the first connecting part 11, the third connecting part 21, and the second connecting part 12 in sequence.

Therefore, the gate drive circuit will not be destroyed by ESD as the detection device in the prior art in which the output end of the gate drive circuit is always connected with the test pad, and the TFT of the gate drive circuit can be prevented from being broken down and destroyed. In other words, according to the present disclosure, a qualified rate of the liquid crystal display panel can be improved.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. A detection device for a gate drive circuit, comprising a test pad and a connecting element for electrically connecting the gate drive circuit and the test pad,
wherein the connecting element comprises a first connecting part, a second connecting part, and a third connecting part;
wherein a first end of the first connecting part is electrically connected with an output end of the gate drive circuit, and a first end of the second connecting part is electrically connected with the test pad; and
wherein a second end of the first connecting part is electrically connected with the third connecting part, and a second end of the second connecting part is electrically insulated from the third connecting part.

2. The detection device according to claim 1,
wherein the first connecting part and the second connecting part are arranged on a first metal layer;
wherein the third connecting part is arranged on a second metal layer; and
wherein the first metal layer and the second metal layer are insulated from each other.

3. The detection device according to claim 2, wherein an insulation layer is arranged between the first metal layer and the second metal layer, so that the first metal layer and the second metal layer are insulated from each other.

4. The detection device according to claim 3, wherein the insulation layer is provided with at least one via hole, and the second end of the first connecting part is electrically connected with the third connecting part through the via hole.

5. The detection device according to claim 2, wherein the first metal layer further comprises a pattern of a scanning line of a display panel and a pattern of a gate of a switching element of the display panel.

6. The detection device according to claim 2, wherein the second metal layer further comprises a pattern of a data line of a display panel and a pattern of a source and a drain of a switching element of the display panel.

7. The detection device according to claim 2,
wherein the insulation layer is made of silicon nitride; and/or
wherein the first metal layer is made of Mo/Al, and the second metal layer is made of Mo/Al/Ge.

8. The detection device according to claim 1, wherein when an abnormity of a panel is detected, an insulating material between the second end of the second connecting part and the third connecting part is melted by a laser so that the second end of the second connecting part and the third connecting part are electrically connected with each other.

9. The detection device according to claim 2, wherein when an abnormity of a panel is detected, an insulating material between the second end of the second connecting part and the third connecting part is melted by a laser so that the second end of the second connecting part and the third connecting part are electrically connected with each other.

10. The detection device according to claim 3, wherein when an abnormity of a panel is detected, an insulating material between the second end of the second connecting part and the third connecting part is melted by a laser so that the second end of the second connecting part and the third connecting part are electrically connected with each other.

11. The detection device according to claim 4, wherein when an abnormity of a panel is detected, an insulating material between the second end of the second connecting part and the third connecting part is melted by a laser so that the second end of the second connecting part and the third connecting part are electrically connected with each other.

12. The detection device according to claim 5, wherein when an abnormity of a panel is detected, an insulating material between the second end of the second connecting part and the third connecting part is melted by a laser so that the second end of the second connecting part and the third connecting part are electrically connected with each other.

13. The detection device according to claim 6, wherein when an abnormity of a panel is detected, an insulating material between the second end of the second connecting part and the third connecting part is melted by a laser so that the second end of the second connecting part and the third connecting part are electrically connected with each other.

14. The detection device according to claim 7, wherein when an abnormity of a panel is detected, an insulating material between the second end of the second connecting part and the third connecting part is melted by a laser so that the second end of the second connecting part and the third connecting part are electrically connected with each other.

15. A detection method for a gate drive circuit, comprising following steps:
providing a detection device, which comprises a test pad and a connecting element for electrically connecting the gate drive circuit and the test pad,
wherein the connecting element comprises a first connecting part, a second connecting part, and a third connecting part;
wherein a first end of the first connecting part is electrically connected with an output end of the gate drive circuit, and a first end of the second connecting part is electrically connected with the test pad; and
wherein a second end of the first connecting part is electrically connected with the third connecting part, and a second end of the second connecting part is electrically insulated from the third connecting part;
determining whether the gate drive circuit needs to be detected; and
if yes, melting an insulating material between the second end of the second connecting part and the third connecting part by a laser, so that the second end of the second connecting part and the third connecting part are electrically connected with each other and an output signal of the gate drive circuit is output through the connecting element and the test pad in sequence.

16. The detection method according to claim 15, further comprising:
determining a state of the gate drive circuit according to a signal output by the test pad.
